(19) United States
(12) Patent Application Publication
(10) Pub. No.: US 2018/0331257 A1
(43) Pub. Date: Nov. 15, 2018

(54) INFRARED LIGHT EMITTING DIODE WITH STRAIN COMPENSATION LAYER AND MANUFACTURING METHOD THEREOF

(71) Applicant: AUK CORP., Jeollabuk-do (KR)

(72) Inventor: Hyung Joo LEE, Jeollabuk-do (KR)

(21) Appl. No.: 15/978,051

(22) Filed: May 11, 2018

(30) Foreign Application Priority Data
May 12, 2017 (KR) 10-2017-0059047

(51) Int. Cl. H01L 33/12; H01L 33/06; H01L 33/00; H01L 33/30

(52) U.S. Cl. CPC H01L 33/12; H01L 33/30; H01L 33/0025; H01L 33/06

(57) ABSTRACT

The present invention relates to an infrared light emitting diode and a manufacturing method thereof, and more specifically, to an infrared light emitting diode with improved light emitting efficiency and a manufacturing method thereof.

The infrared light emitting diode according to the present invention includes a GaAs substrate; a first type AlGaAs lower confinement layer grown on the GaAs substrate; an InGaP strain compensation layer grown on the first type AlGaAs lower confinement layer; an active layer including an InGaAs quantum well grown on the InGaP strain compensation layer; a second type AlGaAs upper confinement layer grown on the active layer; and a window layer.

### BACKGROUND OF THE INVENTION

### Field of the Invention

The present invention relates to an infrared light emitting diode and a manufacturing method thereof, and more specifically, to an infrared light emitting diode with improved light emitting efficiency and a manufacturing method thereof.

### Background of the Related Art

An infrared light emitting diode having a center wavelength of 940±10 nm (hereinafter, referred to as a center wavelength of 940 nm) has a grown n-type AlxGa1-xAs material and a p-type AlxGa1-xAs material (0.1<x<0.7) with substantially the same lattice constant on a GaAs substrate having a high lattice matching rate and high cost reduction (economic feasibility), and has an active layer including an undoped GaAs quantum barrier and an InGaAs quantum well, in which content of In is adjusted to be less than 10% so as to grow on these layers (the n-type and p-type materials and the quantum barrier), between the grown n-type and p-type materials. Generally, the active layer is a multi-structure configured of an InGaAs quantum well and a GaAs quantum barrier. In addition, a p-type AlxGa1-xAs layer of 3 um or more which is a current diffusion layer is grown on uppermost part to maximize the optical efficiency. Such an infrared light emitting diode having a center wavelength of 940 nm is generally manufactured using metalorganic chemical vapor deposition (MOCVD) for growth of high quality.

However, such a structure causes degradation of efficiency since a strain occurs in the InGaAs used as the quantum well of the active layer due to lattice mismatch with the GaAs layer in the growth process.

### SUMMARY OF THE INVENTION

Therefore, the present invention has been made in view of the above problems, and it is an object of the present invention to provide a method of preventing degradation of efficiency caused by lattice mismatch of an infrared light emitting diode having a center wavelength of 940 nm.

Another object of the present invention is to provide a light emitting diode with improved efficiency by compensating for the lattice mismatch of an infrared light emitting diode having a center wavelength of 940 nm.

To solve the problems described above, the infrared light emitting diode having a center wavelength of 940 nm has an InGaP strain compensation layer between a lower confinement layer and an active layer.

Although the present invention is not limited theoretically, since lattice constants of all the n-type layer, p-type layer, quantum barrier and window layer excluding the InGaAs layer of quantum well almost correspond to that of the GaAs substrate material (for example, Aly_{0.3}Ga_{0.7}As/GaAs:Δα/α≤400 ppm; a change rate with respect to the lattice constant) while the lattice constant change rate between the GaAs layer and the InGaAs layer has a high compressive strain (for example, In_{0.07}Ga_{0.93}As/GaAs:Δα/α≤6,000 ppm; a change rate with respect to the lattice constant), efficiency of the active layer of the light emitting diode can be improved by minimizing the rate of the compressive strain generated in the growth process of the InGaAs active layer by inserting a strain compensation layer under the InGaAs active layer, in which the lattice constant of the strain compensation layer almost corresponds to that of the GaAs material, and the strain compensation layer has a tensile strain rate for compensating for the compressive strain rate through control of the composition ratio between In and Ga.

In the present invention, the InGaP strain compensation layer is preferably an InₓGa₁₋ₓP layer (0.44≤x≤0.47), further preferably x=0.47, to enhance light emitting efficiency.

In the present invention, the term ‘compressive strain’ means that the active layer has an arcsec lower than the arcsec of the GaAs substrate.

In the present invention, the term ‘tensile strain’ means that the active layer has an arcsec higher than the arcsec of the GaAs substrate.

In the present invention, an infrared light emitting diode having a center wavelength of 940 nm includes a GaAs substrate; a first type AlGaAs lower confinement layer grown on the GaAs substrate; an InGaP strain compensation layer grown on the first type AlGaAs lower confinement layer; an active layer including an InGaAs quantum well grown on the InGaP strain compensation layer; a second type AlGaAs upper confinement layer grown on the active layer; and a p-type window layer and has an upper electrode and a lower electrode respectively on the top surface and the bottom surface of the p-type window layer and the GaAs substrate.

In the present invention, the GaAs substrate is a substrate on which a lower confinement layer grows, and a lower electrode may be formed on the bottom surface of the substrate. In an embodiment of the present invention, the GaAs substrate may be a type the same as that of the first type AlGaAs lower confinement layer, preferably an n-type GaAs substrate, and for example, the n-type GaAs substrate may have a value of 32.9 arcsec.

In the present invention, the AlGaAs lower confinement layer preferably uses a type the same as that of the lower GaAs substrate and preferably has an arcsec value substantially of the same level as the n-type substrate, i.e., ±0.5 of the arcsec value of the n-type substrate. In a preferred embodiment, the ratio between Al and Ga may be controlled so that AlGaAs may have an arcsec value substantially of the same level as the n-type substrate. For example, AlGaAs may be expressed as AlxGa1-xAs, and x may be 0.3.

In the present invention, the active layer may be a multilayered active layer alternatingly stacking an InGaAs quantum well layer and a GaAs quantum barrier layer.

In an embodiment of the present invention, the InGaAs active layer may use a range of 0.07≤x≤0.08 in the InₓGa₁₋ₓAs layer so as to emit light having a center wavelength of 940 nm, and the range may be controlled slightly according to thickness.

In a preferred embodiment of the present invention, the multilayered active layer may be two or more pairs, preferably three or more pairs, further preferably four or more pairs, and preferably five pairs of InGaAs the quantum well layer and the GaAs quantum barrier.

In the present invention, the upper confinement layer AlGaAs may be expressed as AlxGa1-xAs, and x may be 0.3.

In an aspect of the present invention, there is provided a light emitting diode including a substrate; a lower confinement layer; a strain active layer; an upper confinement layer; and a window layer, wherein a strain compensation layer for compensating for strain of the active layer is further provided between the lower confinement layer and the active layer.

In an aspect of the present invention, there is provided a method of manufacturing a light emitting diode including a substrate; a lower confinement layer; a strain active layer; an upper confinement layer; and a window layer, wherein a strain compensation layer for compensating for strain of the active layer is grown on the lower confinement layer, and the active layer is grown on the strain compensation layer.

In the present invention, it is preferable that a tensile strained compensation layer is formed for the compressively strained active layer and a compressively strained compensation layer is formed for the tensile strained active layer so that efficiency of the light emitting diode may be improved.

### BRIEF DESCRIPTION OF THE DRAWINGS

FIG. 1 is a view briefly showing the structure of a 940 nm infrared light emitting diode applying an InxGa1-xP strain compensation layer manufactured by a MOCVD System.

FIG. 2 is a view showing a result of XRD performed on an InₓGa₁₋ₓP strain compensation layer, an In_{0.07}Ga_{0.93}As quantum well layer, an n-type confinement layer, an Al_{0.3}Ga_{0.7}As layer and a GaAs substrate.

FIG. 3 is a view showing the photoluminescense (PL) characteristic of an active layer of a 940 nm infrared light emitting diode applying an InₓGa₁₋ₓP layer having the tensile strain characteristic obtained in FIG. 2.

FIG. 4 is a graph showing optical characteristics of a 940 nm infrared light emitting diode applying an InₓGa₁₋ₓP strain compensation layer according to the present invention.

DESCRIPTION OF SYMBOLS

| | |
|---|---|
| 1: Upper electrode | 2: Window layer |
| 3: P-type confinement layer | 4: Quantum well |
| 5: Quantum barrier | 6: Strain compensation layer |
| 7: N-type confinement layer | 8: Substrate |
| 9: Lower electrode | 10: Active layer |

### DETAILED DESCRIPTION OF THE PREFERRED EMBODIMENT

Hereinafter, the present invention will be described in detail through an embodiment.

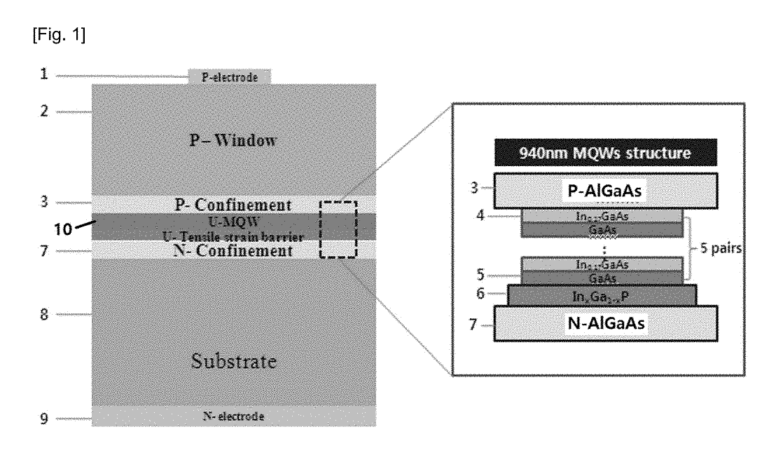

FIG. 1 is a view briefly showing the structure of a 940 nm infrared light emitting diode applying an InxGa1-xP strain compensation layer manufactured by a MOCVD System.

As shown in FIG. 1, a 940 nm infrared light emitting diode configures a lower n-type GaAs substrate 8, an n-type confinement layer 7 of Al_{0.3}Ga_{0.7}As grown on the n-type GaAs substrate, a strain compensation layer 6 of InₓGa₁₋ₓP grown on the n-type confinement layer 7, and an active layer 10 formed by alternatingly growing a quantum barrier 5 of GaAs and a quantum well 4 of In_{0.07}Ga_{0.93}As on the strain compensation layer 6 five times. A p-type confinement layer 3 of Al_{0.3}Ga_{0.7}As is grown up on the active layer 10, and a window layer 2 of Al_{0.2}Ga_{0.8}As is grown up in a thickness of 5 μm on the p-type confinement layer 3 for the effect of current diffusion and discharge cone area expansion of the infrared light emitting diode. A lower electrode 9 of AuGeNi is formed under the GaAs substrate 8, and an upper electrode 1 of AuZn is formed on the window layer 2.

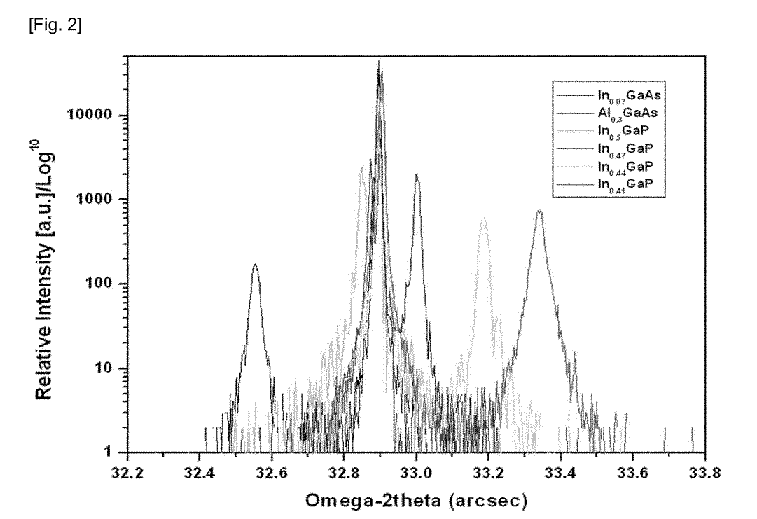

FIG. 2 is a view showing a result of XRD performed on the InₓGa₁₋ₓP strain compensation layer, the In_{0.07}Ga_{0.93}As quantum well layer, the Al_{0.3}Ga_{0.7}As n-type confinement layer and the GaAs substrate. All the layers are grown on the GaAs substrate as a single layer and scanned and measured by omega-2theta. The light emitting diode layers are grown on the GaAs substrate (32.9 arcsec), have a compressive strain when they move in a further lower arcsec direction with respect to the GaAs substrate, and have a tensile strain when they move in a further higher arcsec direction. In the case of In_{0.07}Ga_{0.93}As used as a 940 nm diode light emitting quantum well, it is 32.55 arcsec and confirmed to have a considerably high compressive strain (Δα/α≥6,000 ppm; a change rate with respect to the lattice constant) with respect to the GaAs substrate (32.9 arcsec). Al_{0.3}Ga_{0.7}As used as the n-type confinement layer is 32.85 arcsec and confirmed to have a characteristic (Δα/α≤400 ppm; a change rate with respect to the lattice constant) almost the same as that of GaAs. In the case of the InₓGa₁₋ₓP layer used to compensate for the high compressive strain of In_{0.07}Ga_{0.93}As, it is confirmed that InₓGa₁₋ₓP layer shows various strain characteristics, from the characteristic of a compressive strain (32.82 arcsec) to the characteristic of a tensile strain (33.0, 33.2 and 33.32 arcsec), with respect to the GaAs substrate (32.9 arcsec) according to the ratio of In. In addition, it is confirmed in this experiment that the strain characteristic for the quantum well of In_{0.07}Ga_{0.93}As having a high compressive strain can be compensated using the characteristics of the compressive strain and the tensile strain of the InₓGa₁₋ₓP layer.

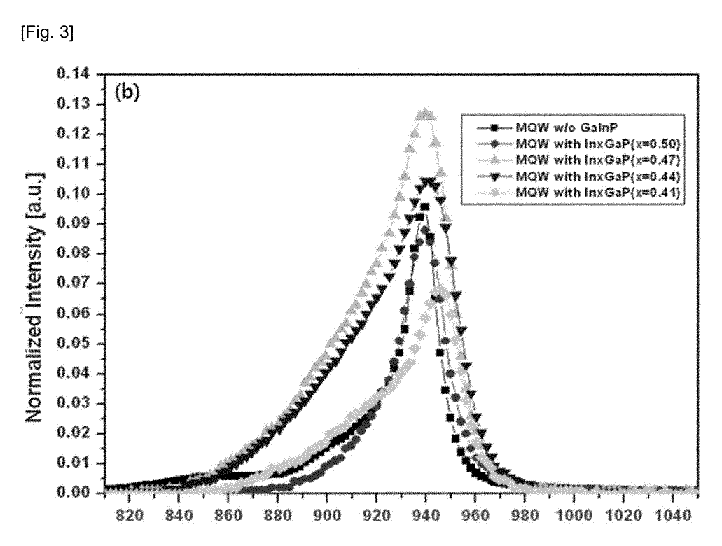

FIG. 3 is a view showing the photoluminescence (PL) characteristic of an active layer of a 940 nm infrared light emitting diode applying the InₓGa₁₋ₓP layer having various strain characteristics (compressive strain and tensile strain) obtained in FIG. 2. The active layer of a basic 940 nm infrared light emitting diode (MQW w/o InGaP) shows a light intensity of 0.1. The active layer of a 940 nm infrared light emitting diode applying the InₓGa₁₋ₓP layer having a compressive strain (MQW with In_{0.5}Ga_{0.5}P) shows a characteristic of a further lower light intensity of about 0.09. Contrarily, the active layer of a 940 nm infrared light emitting diode applying the InₓGa₁₋ₓP layer (0.44<x<0.47) having a tensile strain shows a characteristic of a relatively high light intensity of about 0.13 and 0.11 and shows a considerably lowered light intensity of 0.06 at some of x values smaller than 0.41 (x<0.41). Based on the result, it is understood that if a predetermined condition on the tensile strain is satisfied, the InₓGa₁₋ₓP strain compensation layer is one of the effective methods from the aspect of increasing the efficiency of In_{0.07}Ga_{0.93}As active layer of the 940 nm infrared light emitting diode.

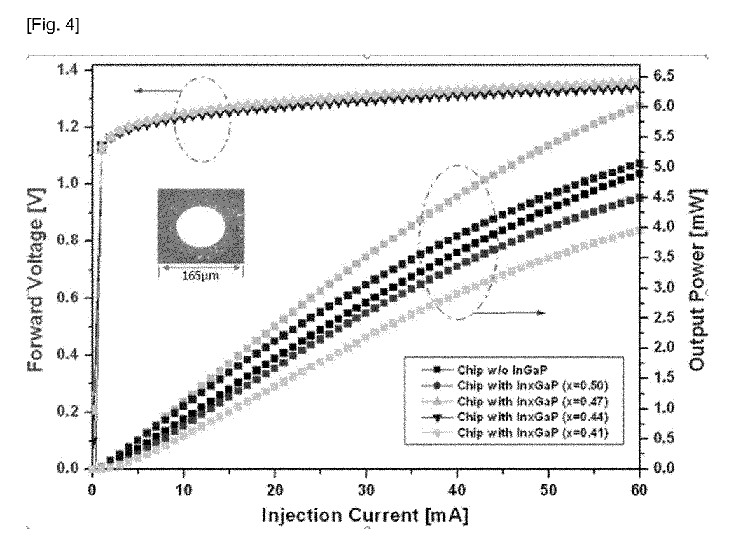

FIG. 4 is a graph showing optical, characteristics of a 940 nm infrared light emitting diode applying an InₓGa₁₋ₓP strain compensation layer developed in the present Invention. The x values of the applied InₓGa₁₋ₓP strain compensation layer are 0.5, 0.47, 0.44 and 0.41, and the strain compensation layer has a characteristic of both the compressive strain and the tensile strain according to an x value. From the developed infrared light emitting diode, current-voltage (I-V) and current-light (I-L) values are measured under the current value applied as high as about 60 mA.

As shown in FIG. 4, the light emitting diode applying the compressive strain of the InₓGa₁₋ₓP layer(x=0.5) shows a light emitting characteristic lower than that of a light emitting diode to which the compressive strain is not applied (w/o InGaP), and such, a result shows that a compressive strain added to the high compressive strain of the In_{0.07}Ga_{0.93}AS layer has a negative effect. Considerably improved light emitting characteristics are confirmed from the light emitting diodes applying the tensile strain of the InₓGa₁₋ₓP layer (0.44<x<0.47), and the efficiency increases about 25% and about 5% at x=0.47. In addition, when an InₓGa₁₋ₓP layer (x=0.41) having a further higher tensile strain is applied, a phenomenon of abruptly lowering the efficiency (about −22%) is confirmed.

According to the present invention, the problem according to the strain of an infrared light emitting diode of a center wavelength of 940 nm using a GaAs substrate having a high lattice matching rate and high cost reduction is solved, and thus an infrared diode with improved light emitting efficiency is provided.

1. An infrared light emitting diode comprising:
a GaAs substrate;
a first type AlGaAs lower confinement layer grown on the GaAs substrate;
an InGaP strain compensation layer grown on the first type AlGaAs lower confinement layer;
an active layer including an InGaAs quantum well grown on the InGaP strain compensation layer;
a second type AlGaAs upper confinement layer grown on the active layer;
a window layer; and
an electrode.

2. The infrared light emitting diode according to claim 1, wherein the infrared light emitting diode has a center wavelength of 940 nm.

3. The infrared light emitting diode according to claim 1, wherein the InGaP strain compensation layer is a compensation layer having a tensile strain rate.

4. The infrared light emitting diode according to claim 1, wherein the InGaP strain compensation layer is an InxGa1-xP layer(0.44<x<0.47).

5. The infrared light emitting diode according to claim 1, wherein the InGaP strain compensation layer is an InxGa1-xP layer(x=0.47).

6. The infrared light emitting diode according to claim 1, wherein the active layer is formed by alternatingly stacking an InGaAs layer and a GaAs layer.

7. A light emitting diode comprising:
a substrate;
a lower confinement layer;
a strain active layer;
an upper confinement layer; and
a window layer, wherein
a strain compensation layer for compensating for strain of the active layer is provided between the lower confinement layer and the active layer.

8. A method of manufacturing a light emitting diode comprising:
a substrate;
a lower confinement layer;
a strain active layer;
an upper confinement layer; and
a window layer, wherein
a strain compensation layer for compensating for strain of the active layer is grown on the lower confinement layer, and the active layer is grown on the strain compensation layer.
